(19) United States
(12) Patent Application Publication
(10) Pub. No.: US 2014/0321083 A1
(43) Pub. Date: Oct. 30, 2014

(54) ELECTRONIC DEVICE WITH EXPANSION CARD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: MING-YU LIU, Shenzhen (CN); GUO-YI CHEN, Shenzhen (CN); AN-GANG LIANG, Shenzhen (CN)

(73) Assignees: HONG FU JIN PRECISION INDUSTRY (ShenZhen) CO., LTD., ShenZhen (CN); HON HAI PRECISION INDUSTRY CO., LTD., New Taipei (TW)

(21) Appl. No.: 13/901,595

(22) Filed: May 24, 2013

(30) Foreign Application Priority Data
Apr. 29, 2013 (CN) 2013101550466

(51) Int. Cl. H05K 7/14

(52) U.S. Cl. CPC H05K 7/1409
USPC 361/754

(57) ABSTRACT

An electronic device includes a chassis, an installation board, an expansion card mounted to a bottom surface of the installation board, and a fixing member. The chassis includes a motherboard forming a socket. The expansion card includes a connector engaged in the socket. The fixing member includes a movable portion including a bar. The movable portion is rotated to drive the bar to lift the installation board away from the motherboard, thereby disengaging the connector from the socket.

### BACKGROUND

1. Technical Field

The present disclosure relates to electronic devices, and particularly to an electronic device including an expansion card.

2. Description of Related Art

Some expansion cards mounted to motherboards are parallel to the motherboards. When such a expansion card is often firmly engaged in a socket mounted on the motherboard, it will be difficult to disengage the expansion card from the socket. If users try to disengage the expansion card from the socket with too much of force, it may destroy the expansion card and pins of the socket.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an electronic device, wherein the electronic device includes an installation board, an expansion card, a supporting member, and a fixing member.

FIG. 2 is an inverted view of the installation board and the expansion card of FIG. 1.

FIG. 3 is an inverted view of the supporting member and the fixing member of FIG. 1.

FIG. 4 is a partially assembled view of FIG. 1.

FIG. 5 is a cross-sectional view of FIG. 4, taken along the line V-V.

FIG. 6 is an assembled view of FIG. 4.

FIG. 7 is a cross-sectional view of FIG. 6, taken along the line VII-VII.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

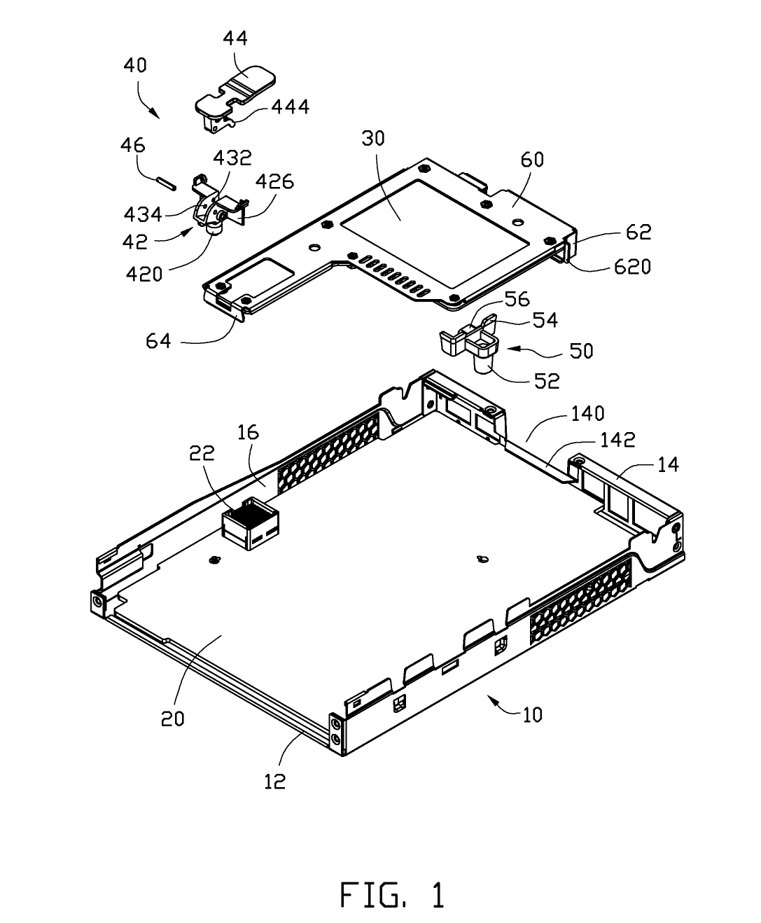

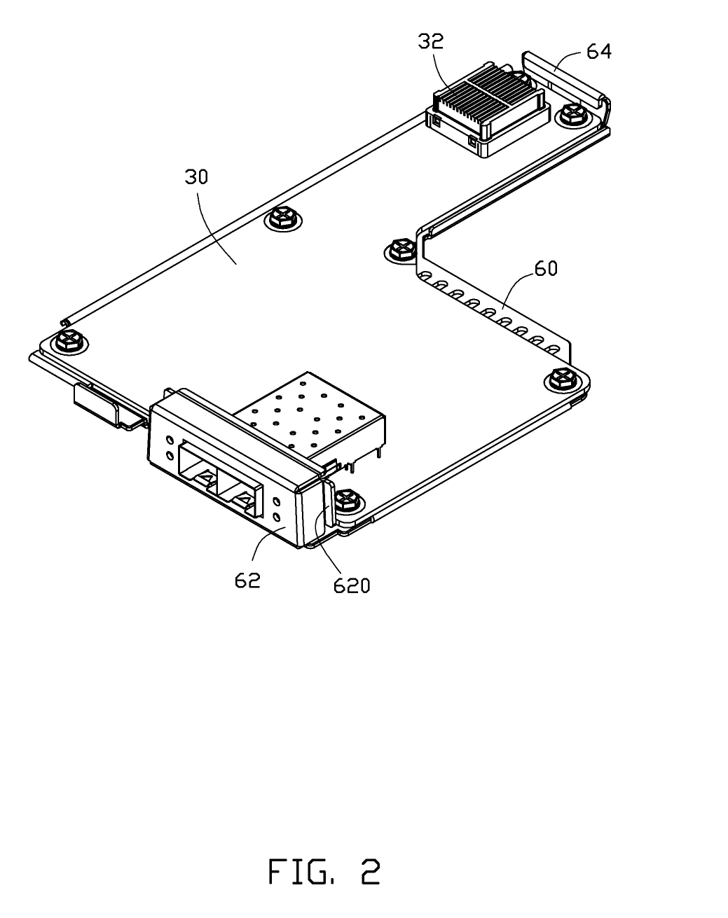

FIGS. 1 and 2 show an embodiment of an electronic device. The electronic device includes a chassis 10, an expansion card 30, a fixing member 40, a supporting member 50, and an installation board 60.

The chassis 10 includes a bottom wall 12, a motherboard 20 mounted on the bottom wall 12, an end wall 14 perpendicularly extending up from an end of the bottom wall 12, and a sidewall 16 perpendicularly extending up from a side of the bottom wall 12. The end wall 14 defines an opening 140 extending through a center of a top of the end wall 14. A socket 22 is mounted to the motherboard 20, adjacent to the sidewall 16, and away from the end wall 14.

A block 62 and an extension piece 64 extend down from opposite ends of the installation board 60. Two tabs 620 extend out from opposite ends of an inner side of the block 62 facing the extension piece 64.

The expansion card 30 is mounted to the bottom of the installation board 60. A connector 32 is mounted to a bottom of the expansion card 30 and adjacent to the extension piece 64.

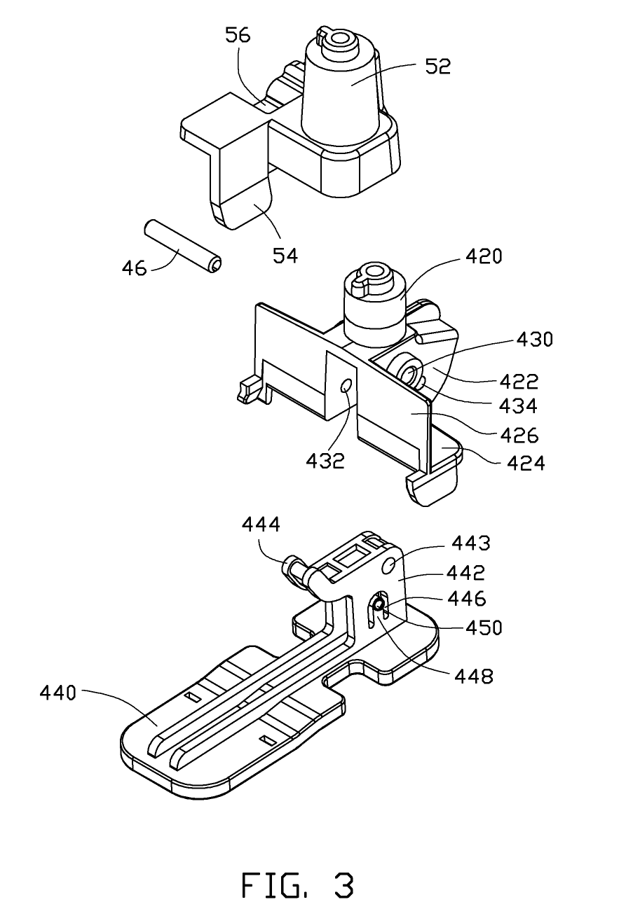

FIGS. 1 and 3 show that the fixing member 40 includes a base 42, a movable portion 44, and a pole 46.

The base 42 includes a rod 420, two arms 422 extending up from a top of the rod 420, two supporting pieces 424 extending away from each other from tops of the arms 422, two blocking pieces 426 each perpendicularly connected between one of the arms 422 and the adjacent supporting piece 424. Each arm 422 defines a pivot hole 430, and a first engaging hole 432 and a second engaging hole 434 above the pivot hole 430. The second engaging hole 434 is away from the blocking piece 426.

The movable portion 44 includes an operation portion 440 and a mounting portion 442 extending down from a first end of a bottom surface of the operation portion 440. A through hole 443 is defined in a first end of a lower portion of the mounting portion 442. A bar 444 extends out from a second end of the mounting portion 442 and then extends downward. The mounting portion 442 defines a slot 446 extending through opposite sides of the mounting portion 442. Two resilient pieces 448 extend down from a top wall bounding the slot 446, adjacent to opposite ends of the slot 446. A projection 450 protrudes out from a lower portion of each resilient piece 448.

The supporting member 50 includes a rod 52, a blocking piece 54 extending up from a top of the rod 52, and a supporting piece 56 extending out from the top of the rod 52 and perpendicular to a circumference of the rod 52.

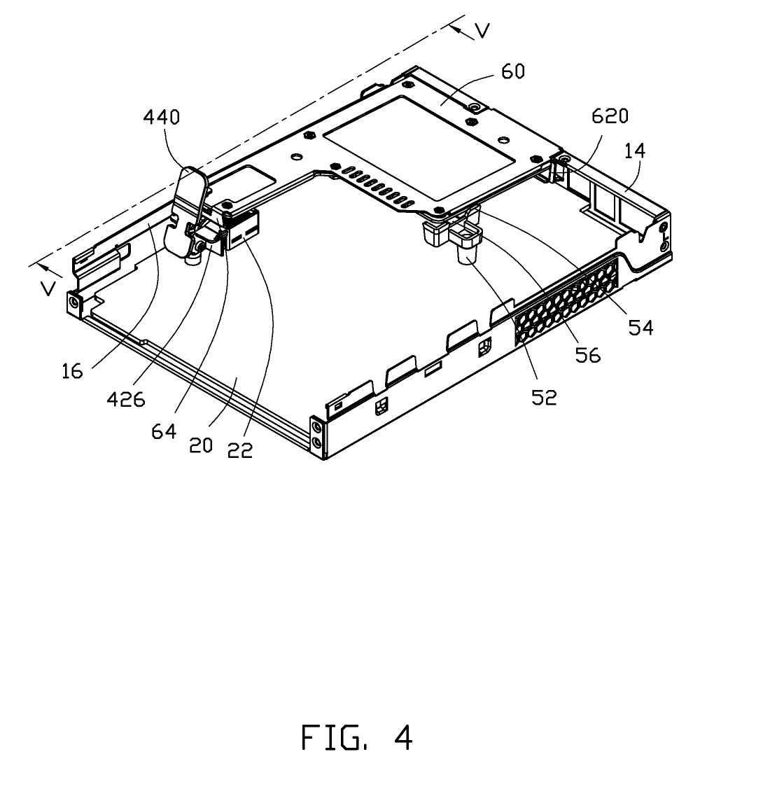

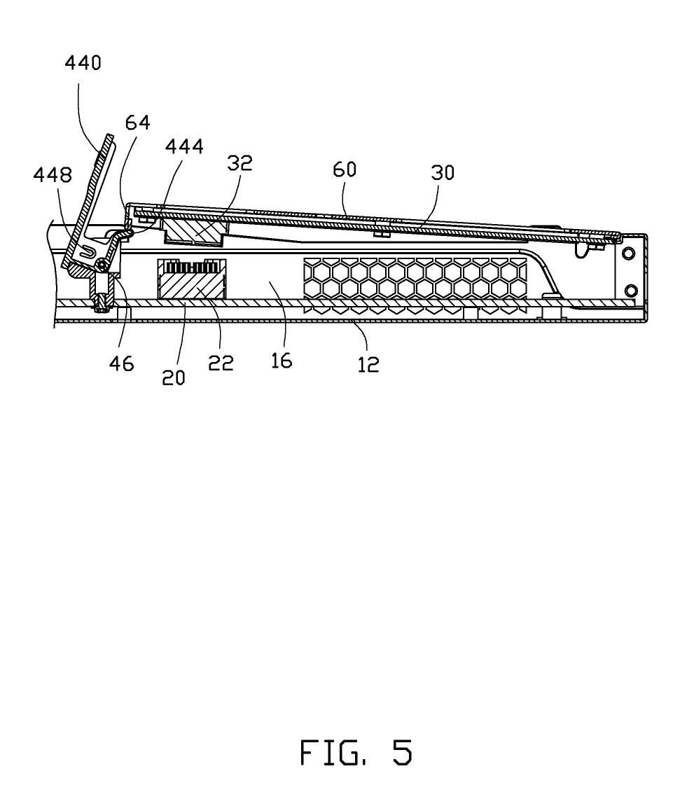

FIGS. 4 and 5 show that in assembly, the mounting portion 442 is movably received between the arms 422. The through hole 443 aligns with the pivot holes 430. The pole 46 extends through one of the pivot holes 430, the through hole 443, and the other pivot hole 430, to pivotably mount the movable portion 44 to the base 42. The first end of the operation portion 440 is positioned upon the supporting pieces 424.

The rods 420 and 52 are engaged in the motherboard 20. The fixing member 40 is adjacent to a side of the socket 22 away from the end wall 14. The supporting member 50 is positioned between the socket 22 and the end wall 14, but away from the sidewall 16. The operation portion 440 is manipulated to pivot the movable portion 44 about the pole 46, keeping the operation portion 440 slanting relative to the bottom wall 12.

The block 62 is received in the opening 140 and contacts a bottom surface 142 bounding the opening 140. The tabs 620 contact an inner surface of the end wall 14. The connector 32 is aligned with the socket 22. The bar 444 is positioned under the extension piece 64.

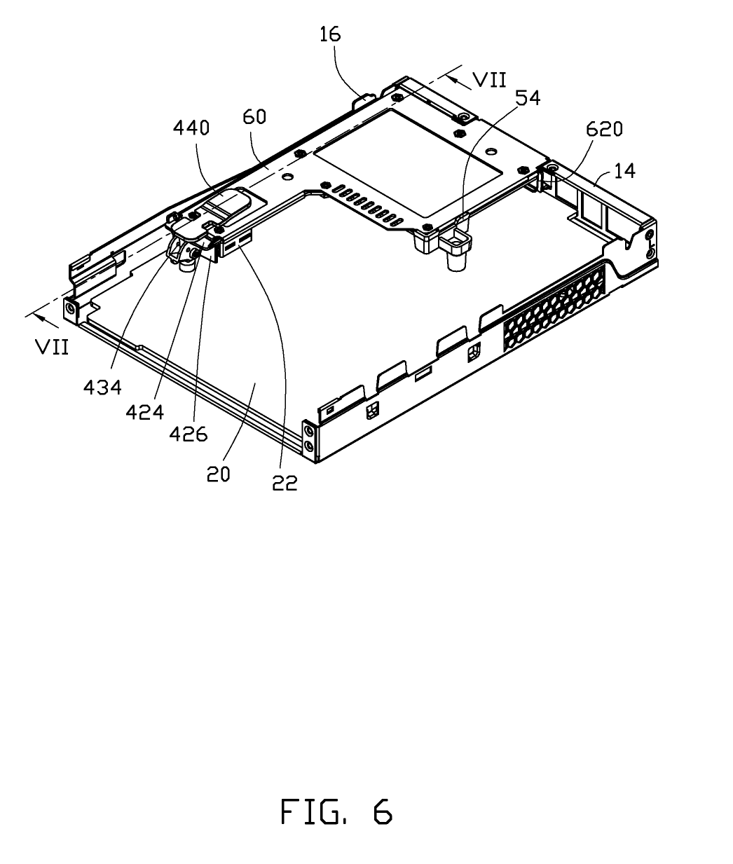

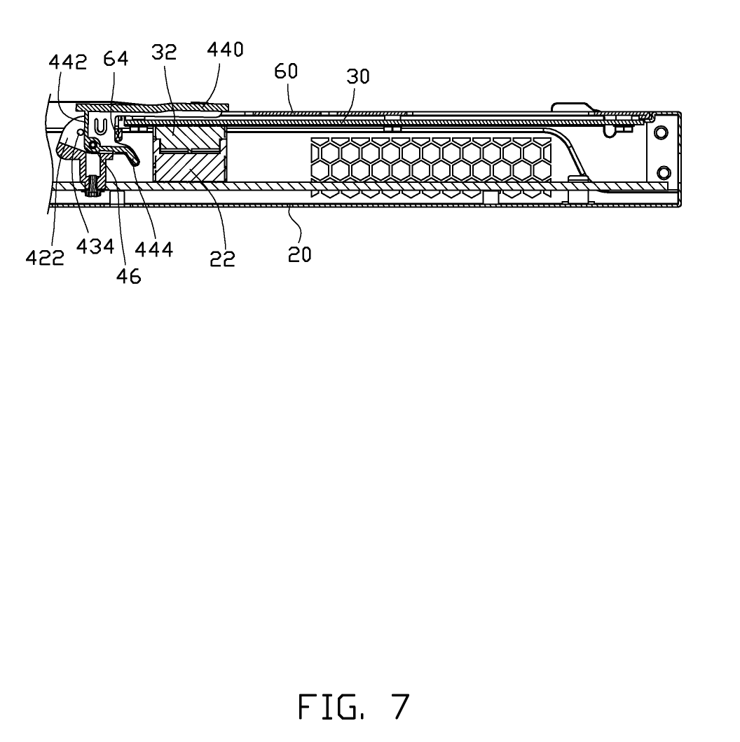

FIGS. 6 and 7 show that the operation portion 440 is pivoted downward about the pole 46, to push the installation board 60 down, until resting on the supporting piece 56. The connector 32 engages in the socket 22. The installation board 60 is sandwiched by the end wall 14, the sidewall 16, and the blocking pieces 54 and 426. The operation portion 440 is blocked by a top surface of the installation board 60. The projections 450 are engaged in the first engaging holes 432. The first end of the operation portion 440 rests on the supporting pieces 424.

A top wall (not shown) of the chassis 10 is then mounted to the chassis 10, presses the operation portion 440, fastening the expansion card 30 to the motherboard 20 tightly.

FIGS. 4 and 5 show that in uninstalling the expansion card 30, the operation portion 440 is pivoted upward. The bar 444 moves upward and lifts the extension piece 64 away from the motherboard 20, thereby disengaging the connector 32 from the socket 22. At this time, the projections 450 can be engaged in the second engaging holes 434.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An electronic device, comprising:
a chassis;
a motherboard mounted in the chassis, wherein a socket is mounted on the motherboard;
an installation board;
an expansion card mounted to a bottom of the installation board, a connector extending from a bottom of the expansion card and engaged in the socket; and
a fixing member mounted to the motherboard and adjacent to the socket, the fixing member comprising a movable portion, the movable portion comprising a bar, wherein, when releasing the expansion card, the movable portion is pivoted to move the bar up to lift the installation board up and away from the motherboard, thereby disengaging the connector from the socket.

2. The electronic device of claim 1, wherein the chassis further comprises a bottom wall and an end wall perpendicularly connected to the bottom wall, the motherboard is mounted on the bottom wall, the end wall defines an opening, a block extends from a first end of the installation board to be received in the opening, two tabs extend from opposite ends of the block to contact an inner surface of the end wall.

3. The electronic device of claim 2, wherein an extension piece extends down from a second end of the installation board opposite to the block, the bar of the fixing member lifts the installation board up by moving the extension piece away from the motherboard.

4. The electronic device of claim 3, wherein the fixing member comprises a blocking piece blocking the extension piece, the installation board is sandwiched between the blocking piece and the end wall.

5. The electronic device of claim 2, further comprising a supporting member, the supporting member comprises a rod fixed to the motherboard, a supporting piece perpendicularly extending out from the rod to support the installation board.

6. The electronic device of claim 5, wherein a sidewall perpendicularly extends up from a side of the bottom wall, a blocking piece extends up from the rod to sandwich the installation board together with the sidewall.

7. The electronic device of claim 1, wherein the movable portion further comprises an operation portion blocked by a top surface of the installation board opposite to the expansion card.

8. The electronic device of claim 7, wherein the fixing member further comprises a rod fixed to the motherboard and two arms connected to a top of the rod, a mounting portion extends down from the operation portion to be movably received between the arms, the bar extends out from the mounting portion and then extends downward.

9. The electronic device of claim 8, wherein the fixing member further comprises a pole rotatably extending through one of the arms, the mounting portion, and the other arm.

10. The electronic device of claim 8, wherein each arm defines a first engaging hole and a second engaging hole, two projections protrude from opposite sides of the mounting portion, when the projections are engaged in the first engaging holes, the operation portion is blocked by the top surface of the installation board, when the projections are engaged in the second engaging holes, the bar moves the extension piece away from the motherboard.

11. The electronic device of claim 10, wherein two resilient pieces are connected to the opposite sides of the mounting portion, the projections protrude from the resilient pieces.

12. The electronic device of claim 11, wherein the mounting portion defines a slot extending through the opposite sides of the mounting portion, the resilient pieces extends from a sidewall bounding the slot.
